(19) United States
(12) Patent Application Publication
(10) Pub. No.: US 2010/0186797 A1
(43) Pub. Date: Jul. 29, 2010

(54) Solar Leaves and Solar Tree Forest - A Solution for Energy Crisis

(76) Inventor: HEMANT NARAHAR JOSHI, Parsippany, NJ (US)

Correspondence Address: HEMANT N. JOSHI/TARA ENTERPRISES, 41 LEAH WAY, PARSIPPANY, NJ, 07054, US

(21) Appl. No.: 12/359,312

(22) Filed: Jan. 24, 2009

(51) Int. Cl. H01L 31/052; H01L 31/042

(52) U.S. Cl. 136/246; 136/244

(57) ABSTRACT

Solar leaves bearing solar films on the top surface and a reflective bottom surface can be attached to a solar tree or to a solar vine through a flexible petiole to convert sunlight into electricity. The electricity produced and be stored in a storage battery or can be sent to the national grid via an inverter. A group of solar trees can be put together in one area creating a solar forest to produce electricity from sunlight collectively.

### BACKGROUND OF THE INVENTION

With over 6 billion population worldwide, the rate of consumption of natural resources has been increased to highest levels in recent decades. Several sources of energy have been explored including oil, nuclear, wind, tidal and solar. Every energy source has its own limitations. The solar energy is the only energy source which has tremendous promises due to the infinite supply. The sunlight consists of photons, which are nothing but bundles of energy. In a simplest form of energy conversion, sunlight can warm water generating heat energy. Plants convert solar energy into food by the photosynthesis process. Sunlight can cook food such as in the rice cooker.

Solar cells convert the solar energy into an electrical energy. In solar cells, when a photon hits a semi-conducting material such as silicone, the electrons are knocked off producing electricity. An array of solar panels is used to produce Direct Current (DC) electricity.

There are two kinds of solar cell technologies: stand-alone and a grid-kind. In a stand-alone system, the solar light falling on the panels is used to charge batteries. In a grid-kind system, with a help of an inverter, the solar energy is fed to the national electric grid. The current solar panels, which can produce a significant quantity of energy, are big and bulky. Newer ways are used to produce different designs of solar panels. A company (Xnox) has prepared films, which can adhere to windows and can convert the solar energy into an electrical energy. Recently, IBM announced a partnership with Tokyo Ohka Kogyo Co. Ltd., to produce next generation solar energy products; especially thin film CIGS (copper-indium-gallium-selenide) solar cell modules. Most of the sun's energy is emitted at less than 2-micron wavelength. Part of the solar energy is radiated back, but at a longer wavelength, such as an infrared radiation. It will be beneficial if the solar films have high capacity to absorb radiations below 2-micron and should not emit radiations at longer wavelengths. U.S. Pat. No. 4,437,455 described a multilayer solar energy collector containing copper oxide, cobalt oxide, and manganese oxide to do the same. The multilayer also contained platinum, quartz and silicate glass. The US patent application 2008/0075948 disclosed a tear resistant solar control multilayer films with alternating polymeric layers and contain a layer of infrared light absorbing metal oxide nanoparticles. A solar cell of 12% efficiency with a 100 cm² (0.01 m²) surface area can be expected to produce approximately 1.2 watts of power. The new solution-based manufacturing process may increase the efficiencies to about 15% and higher from the current efficiencies of six (using amorphous silicone) to 23% (for a high quality single crystal silicone cell). Intel has invested significantly in Sulfurcell, a leading German developer and manufacturer of thin-film, electricity-generating solar modules. Sulfurcell makes monolithic modules using thin-film materials from the CIS/CIGSe (Copper-Indium-Sulfide/Selenide) family of chemical elements for the conversion of light to electricity.

Solar panels have limitations too. Shading and dirtying of even few panels can cause drop of more than 50% efficiency of the solar panels. National Semiconductor has come up with a Solar Magic Technology™, which allows the weakest solar panel to function independently without affecting the output of other panels. It has been observed that the solar panels have negative temperature coefficient. As a result, the power output is lower at higher temperatures.

Using carbon dioxide, water and minerals, with the help of solar energy, plants have been producing sugars and amino acids for thousands of years efficiently. Plants ensure the exposure of each of their leaves to sunlight so that they can run the photosynthesis process efficiently.

### SUMMARY OF THE INVENTION

The current invention describes the design of a solar leaf, a solar tree and a solar forest. The same principle can be applied to make solar vines. A group of solar trees, when put together, forms a forest of solar trees to convert solar energy into electricity collectively. The solar tree is either anchored in the ground or fixed to a structure (such as a building) to keep it above ground. A solar tree has a similar structure as that of a natural tree—having a trunk, branches, sub-branches, and leaves. The solar leaves are the key element converting solar energy into an electrical energy. In a variation, solar films can also be applied on trunk, branches and sub-branches. A solar leaf provides as a base to adhere solar films. It also provides a maximum exposure to sunlight to capture photons. The branches and the trunk have two functions—provide support to leaves allowing a proper exposure to the sunlight and provide support to electrical conduits carrying newly generated electricity. In cases when they bear solar films, they will generate electricity too from the sunlight.

The photons from the solar rays bombarding on the semiconductor material can get absorbed into the semiconductor material forming electricity. Part of the solar energy may convert into heat or it may be emitted back in the atmosphere. Increase in temperature is known to reduce the efficiency of solar cells. The special design of the solar tree allows lowering of temperature of the solar films improving their efficiency compared to solar panels. The petiole of a solar leaf allows the free movement of leaves so that incident solar rays can be absorbed efficiently. The movement of leaves with wind keeps the temperature of solar leaves low and throws off the dust from leaves keeping them clean. Rain will also wash off dust from the solar leaves. The solar leaves also provide more electricity-producing surface area improving its efficiency.

The factors governing exposure to solar rays are—height of the tree, arrangement of branches and sub-branches (racemose, cymose, phyllotaxy (alternate/spiral)), shape of leaves (simple and compound), and number of leaves. In general, the leaves are kept horizontal to gather maximum light. The solar leaves are not just flat but can also be curved with front side curving downwards to earth. Leaves form many planes in relation to the stem to receive maximum light. These arrangements are called mosaic or pattern. The commonly used mosaic in this inventions are—rosette for crowded leaves, imbricate which are more like shingles, and radiates which are radiating in all directions from the horizontal plane. The purpose is to capture maximum sunlight and convert it to form electricity. The invention uses films of solar cell modules placed on artificial leaves. The discovery proposes to use an array of solar ray absorbing materials allowing a full spectrum of band gaps improving the efficiency of conversion. The veins in the leaves are used as conduits for electricity towards petiole. The electricity is then carried to the inverter through branches and the trunk.

The solar leafy structure has two strata—the top strata providing support to the electricity-producing solar film and the bottom spongy/porous strata allowing passage of air to cool the electricity producing film on the top strata. The lower surface of the solar leaf has high reflection coefficient. The portion of light reflected from the top surface reflects back from the lower surface of the leaves in the plane above. In another version, the lamina of a solar leaf has small holes through which air can reach the electricity producing film. The lamina also has veins through which electrical conduits can reach the stem and then to the inverter.

In another embodiment, an artificial branch bearing solar leaves can be attached to a natural tree to produce electricity from sunlight. A care must be taken not to take away all the natural leaves so that the tree stays alive for many years.

In another embodiment, a solar vine is produced with a thin stem with solar leaves attached to it to be kept outdoors or in the house.

### DETAILED DESCRIPTION

A “solar tree” is defined as an artificial tree with a trunk, branches, sub-branches and electricity producing solar leaves. In another version, solar leaves or an artificial branch with solar leaves are attached to a sub-branch or branch of a natural tree.

A “solar vine” is defined as an artificial vine with a thin flexible stem, branches and electricity producing solar leaves.

A “solar forest” is defined as a group of solar trees with or without solar vines put together in one area randomly or in a symmetrical fashion to produce electricity from sunlight collectively.

A “natural tree” is defined as a tree grown naturally which is alive and conducts all the normal functions of a tree such as photosynthesis.

An “inverter” is an electrical device, which converts the direct current (DC) produced through the solar cells to the alternating current (AC) of desired wattage and feeds it to the national grid for usage.

A “storage battery” is defined as the battery, which can store the electricity produced by solar cells and can be used at later time.

As mentioned earlier, the photons in solar rays are bundles of energy. Photons with lower energy, when hit a piece of silicone, passes through it. Some of these photons can convert into heat energy. Some of the photons can simply reflect from the surface. If an incident photon has higher energy than the silicone band gap (energy gap) value, it can transfer the energy to an electron in the crystal lattice. The term “band gap” or “energy gap” refers to the energy difference between the top of the valence band and the bottom of the conduction band. The band gap is different for different materials. The electrons can get sufficient energy to jump from the valence band to the conduction band by absorbing either a phonon (heat) or a photon (light). The electron in the valence band is tightly bound in the covalent bonds between neighboring atoms. When the electron is excited by a photon and leaves the covalent bond, the covalent bond has one fewer electron, creating a “hole”. An electron from the neighboring atom moves to this hole leaving another hole behind creating mobile electron hole-pairs. Solar cells are made up of P-N junctions. The P-N junctions are made up with P-type (positive) and N-type (negative) semiconductors. P-type semiconductors accept electrons whereas N-type semiconductors donate weakly bound donor electrons. Different types of materials are added to silicone to produce P-type and N-type semiconductors. The electric field established across the P-N junction creates a diode that promotes current to flow in only one direction across the junction. In a simplistic form, the N-type semiconductors are diffused on top of the P-type wafer to form a P-N junction. This invention is not about the design of solar cells but about an application thin film photovoltaic cells (TFPV). TFPV are being developed to be glued to glass windows. The current invention refers to the usage of solar films on solar leaves to produce electricity from the sunlight.

A typical plant structure has a trunk/stem anchored in the ground by a root system. The trunk divides into branches, sub-branches and twigs, which bear leaves. A leaf has a flat surface, which is the main source for plants to capture solar energy. Leaves are attached to a twig or a branch through a petiole. The petiole allows flexibility to the leaf so that it can twist and turn in any direction with the wind but it does not break easily. The flexibility of leaves helps to drain water off the surface. The motion also helps to clean off dust from the leaves. It also helps to keep the temperature of leaves low. Plants, using solar energy, produce sugars, amino acids and many other chemicals in the photosynthesis process. A tree has hundreds and thousands of leaves scattered from top to bottom. A typical plant has many planes for leaves. Each plant has a unique mosaic or design of spread of leaves. Plants have generated a natural mechanism exposing each and every leaf to sunlight by the mosaic of leaves and by swaying of branches, twigs and leaves. Phyllotaxy is the arrangement of leaves on the stem of a tree. There are several kinds of arrangements such as connate, perfoliate, clasping, sessile, petiolate and sheathing. Every leaf has a set of parallel veins and in between, there is a networking of microscopic veins. The venation is complex for compound leaves.

A solar tree has a structure similar to that for a natural tree.

The trunk or stem of the solar tree is either hollow metallic, plastic, wooden or cement tube or a suitable combination of these, with diameter ranging from two to 40 inches at the bottom and it may taper to the top. It is anchored in the ground by concrete or can be attached to a structure to keep it at a desired height away from the ground. If it is a metallic, it can be in form of an alloy and can be coated with plastic to prevent rusting. The height of the trunk is from 1 foot to 100 feet. If it is made up of wood, it may be coated with suitable formulations to prevent rotting. The trunk has to withstand harsh weather for many years, ranging from 10 to 30 years. The trunk can also be coated with light-reflective material. The trunk has small windows at suitable intervals as electric cables are run through the trunk and can be accessed, if necessary. There is an inverter placed at the base of the trunk. If there are many solar trees near each other, one common inverter can be used. The solar trees can be placed in various arrays—in line, in circular fashion or any other random fashion. The distance between solar trees should be such that the leaves from neighboring tree should not block the sunlight.

The branches are placed at suitable intervals on the trunk. Only one branch can placed at a certain height which may allow minimizing overlap of leaves. If two branches are created at one point on the trunk, attention must be given to the strength of the joint. In some cases, a “Y” shaped junction can be placed creating two branches. The joint between the branches and the trunk is vital. It should be strong, but also will allow withstanding stress due to movement of branches. The diameter of branches would vary at different heights of the trunk; the diameters would decrease as branches are away from the ground. The diameter of the branches would vary from one to 12 inches. The length of a branch near ground will be more and the length would decrease for branches away from the ground. Overall, the length of branches can vary from three to 30 feet. The branches are hollow and made up with a metal or an alloy, wood or plastic.

The branches are divided into sub-branches or twigs and their diameter is from one to 8 inches. The joint between a branch and its sub-branch has to be very strong and would withstand a stress due to constant swaying of sub-branches. Branches or sub-branches bear solar leaves.

Solar leaves can be simple or compound. The leaves can have various shapes such as sword-shaped, lance-shaped, spear-shaped, ovate, elliptic, round, cordate, oblanceolate, spathulate, rhomboid, lobed, pinnatisect, pinnate, bipinnate, tripinnate, trifoliate, palmate, digitate, peltate, and rosette. A leaf is attached to a twig, sub-branch or to a branch through a petiole. A petiole is the key component of a solar tree as it allows flexibility to the solar leaf. The flexibility of the solar leaf is vital to its efficiency in creating solar power. The arrangement of solar-leaves on the twigs could be different.

A solar leaf has two distinct surfaces. The top surface is exposed to sunlight bearing TFPV cell and is responsible for generating electricity. Many companies are working towards thin film solar cell modules. In coming years, more types of such thin film solar modules may be developed. This invention is not for the thin film solar device, but an application of the same. Solar light incident on the upper surface of the solar leaf is converted to electricity, or heat energy or some part is reflected. This reflected light from the top surface will be reflected from the bottom surface of the leaf above. Such a reflection will allow conversion of nearly all the incident solar light to electricity improving the efficiency. The bottom surface of the solar leaf is porous. Because of its porosity, it allows air inside the leaf and thereby cooling it. The holes are minute prohibiting an easy access to water. It has been proved already that the efficiency of conversion is reduced as the temperature of solar modules increase. Such a cooling of leaf from the bottom surface will help to increase the efficiency.

The surface area of the solar leaf can range from one cm² to 1000 cm² and most preferably from 1 cm² to 50 cm². Because there are hundreds of leaves on a solar tree, the total area for the conversion of sunlight to electricity is very large. The current solar panels are mounted on a support and they have limited movement within a day and during different months of the year. The angle of solar panels needs to be adjusted based on the position of the panel compared to equator. Solar leaves are flexible and will be moving continuously. A solar leaf has a mesh of veins carrying electric current towards the main vein in the middle. The main vein runs through the petiole towards the twig.

The electricity produced using the solar tree is either stored in the batteries or it is fed to the national grid using an inverter. The current technology can be used for the same.

What is claimed is:

1. A solar tree consisting of solar leaves, sub-branches, branches, and a trunk to produce electricity from sunlight.

2. A solar forest comprising of a group of solar trees with or without solar vines to produce electricity from sunlight collectively.

3. A solar leaf as in claim 1, which can have various shapes including sword-shaped, lance-shaped, spear-shaped, ovate, elliptic, round, cordate, oblanceolate, spathulate, rhomboid, lobed, pinnatisect, pinnate, bipinnate, tripinnate, trifoliate, palmate, digitate, peltate, and rosette.

4. A solar leaf as in claim 1, wherein an electricity producing thin film solar module is on the top surface and may have a light reflecting film on the porous lower surface.

5. A solar leaf as in claim 1 whose area is from 1 cm² to 1000 cm², preferably 1 cm² to 500 cm², more preferably 1 cm² to 100 cm² and most preferably 1 cm² to 50 cm².

6. A solar leaf in claim 1 with a flexible petiole allowing it to swing in all directions in the wind helping to keep the dust off and lower the temperature of the thin film solar module.

7. A branch, sub-branch or the trunk of a solar tree as in claim 1 made up of wood, plastic, cement or metal.

8. A solar tree as in claim 1 whose height is from 1 foot to 100 feet, preferably 1 foot to 70 feet, more preferably 1 foot to 50 foot and most preferably from 1 foot to 30 feet.

9. A solar tree as in claim 1 which is anchored in a ground or it is fixed onto a structure away from ground.

10. A solar tree as in claim 1, wherein the electricity produced from the solar light is sent to the national grid through an inverter or the electricity is stored in a storage battery.

11. A solar forest as in claim 2, wherein the electricity produced from the solar light is sent to the national grid through an inverter or the electricity is stored in a storage battery.

12. Solar leaves or branches bearing solar leaves as in claim 1, which are attached to a natural tree to produce electricity from the sun light.
